(19) United States
(12) Patent Application Publication
(10) Pub. No.: US 2025/0305147 A1
(43) Pub. Date: Oct. 2, 2025

(54) METAL-CONTAINING FILM AND METHOD FOR PRODUCING METAL-CONTAINING FILM

(71) Applicant: Tokyo Electron Limited, Minato-ku, Tokyo (JP)

(72) Inventors: Koji AKIYAMA, Nirasaki City, Yamanashi (JP); Chihiro TAMURA, Nirasaki City, Yamanashi (JP); Hiroaki ASHIZAWA, Nirasaki City, Yamanashi (JP)

(21) Appl. No.: 18/569,248

(22) PCT Filed: Jun. 6, 2022
(86) PCT No.: PCT/JP2022/022760

§ 371 Date: Jun. 13, 2024

(30) Foreign Application Priority Data
Jun. 18, 2021 (JP) 2021-101521

(51) Int. Cl. C23C 28/00; C23C 14/06; C23C 14/14; C23C 14/34; C23C 16/08; C23C 16/34; C23C 16/455; H10D 1/68

(52) U.S. Cl. CPC C23C 28/30; C23C 14/0641; C23C 14/14; C23C 14/34; C23C 16/08; C23C 16/34; C23C 16/45553; H10D 1/696

(57) ABSTRACT

A metal-containing film having a laminate structure that does not contain grain boundaries, wherein the laminate structure is formed by alternately laminating a first metal-containing unit film which has a thickness less than a crystal nucleation critical diameter, and a second metal-containing unit film which differs from the first metal-containing unit film and has a thickness less than the crystal nucleation critical diameter.

### TECHNICAL FIELD

The present disclosure relates to a metal-containing film and a method for producing the metal-containing film.

### BACKGROUND

When producing semiconductor devices, metal-containing films are often used as wires, electrodes, barrier films, metal hard masks, and the like. Such metal-containing films are required to have characteristics, such as low resistance, high mechanical strength, and low atomic diffusion, depending on their respective applications, and various techniques have been proposed for that purpose. For example, Patent Document 1 discloses that, by using CoW as a seed layer of a metal wiring layer containing tungsten (W) as a main component, the crystals of the metal wiring layer are made finer and the deposition resistance value of the metal wiring layer can be kept low.

### PRIOR ART DOCUMENT

### Patent Document

Patent Document 1: Japanese Laid-Open Patent Publication No. 2018-73949

### SUMMARY

The present disclosure provides a metal-containing film having favorable characteristics tailored to its application and a method for producing the same.

A metal-containing film according to an aspect of the present disclosure has a laminate structure that does not contain grain boundaries, wherein the laminate structure is formed by alternately forming a first metal-containing unit film having a thickness less than a crystal nucleation critical diameter, and a second metal-containing unit film, which differs from the first metal-containing unit film and has a thickness less than the crystal nucleation critical diameter.

With the present disclosure, a metal-containing film having favorable characteristics tailored to its application and a method for producing the same are provided.

### BRIEF DESCRIPTION OF DRAWINGS

FIG. 1 is a cross-sectional view schematically illustrating a metal-containing film according to an embodiment.

FIG. 2 is a view illustrating calculation values of crystal nucleation critical diameters D′ of main metals.

FIG. 3 is an SEM photograph of Sample A in which a thickness of an Al film was set to less than 1.7 nm when producing a metal-containing film having an Al—Ti laminate structure by sputtering.

FIG. 4 is an SEM photograph of Sample B in which a thickness of an Al film was set to 1.7 nm or more when producing a metal-containing film having an Al—Ti laminate structure by sputtering.

FIG. 5 is an SEM photograph of Sample C manufactured under the same conditions as Sample A except that the total film thickness was 1,000 nm.

FIG. 6 is an SEM photograph showing an enlarged cross section of Sample C.

FIG. 7 is a diagram showing a transition of free energy during phase transition from an amorphous state, which is a metastable state, to a crystalline state, which is a stable state.

FIG. 8 is a diagram showing relationships (calculation values) between degrees of supercooling and a critical nuclear radii r* of various metals.

FIG. 9 is a diagram showing relationships between degrees of supercooling and the cooling rates in Al—Si alloys.

FIG. 10 illustrates SEM photographs showing states in which a metal-containing film having an Al—Ti laminate structure and a metal-containing film having an (AlSi)—Ti laminate structure were formed by sputtering to thicknesses of 500 nm and 1,000 nm.

FIG. 11 is a diagram showing relationships between degrees of supercooling and the cooling rates in Al—Mg alloys.

FIG. 12 shows SEM photographs of a metal-containing film having an (AlSi)—Ti laminate structure and a metal-containing film having an (AlMg)—Ti laminate structure.

FIG. 13 is an Al—Si phase diagram.

FIG. 14 is an Al—Mg phase diagram.

FIG. 15 is a cross-sectional view illustrating an example of a fine wiring structure in which a metal-containing film of an embodiment is applied to fine wiring.

FIG. 16 is a cross-sectional view illustrating an example of a fine wiring structure in which a metal film of an embodiment is applied to a barrier film.

FIG. 17 is a cross-sectional view illustrating an example of a capacitor in which a metal-containing film of an embodiment is applied to a pillar-structured electrode.

FIG. 18 is a cross-sectional view illustrating an example of a capacitor in which a metal-containing film of an embodiment is applied to a cylinder-structured electrode.

FIG. 19 is a cross-sectional view illustrating an example of a structure in which a metal-containing film of an embodiment is applied to a hard mask.

FIG. 20 is a cross-sectional view illustrating an example of a plasma sputtering apparatus for performing film formation by PVD.

FIG. 21 is a cross-sectional view illustrating an example of a film forming apparatus for performing film formation by ALD or CVD.

### DETAILED DESCRIPTION

Hereinafter, embodiments will be described with reference to the accompanying drawings.

### <Metal-Containing Film>

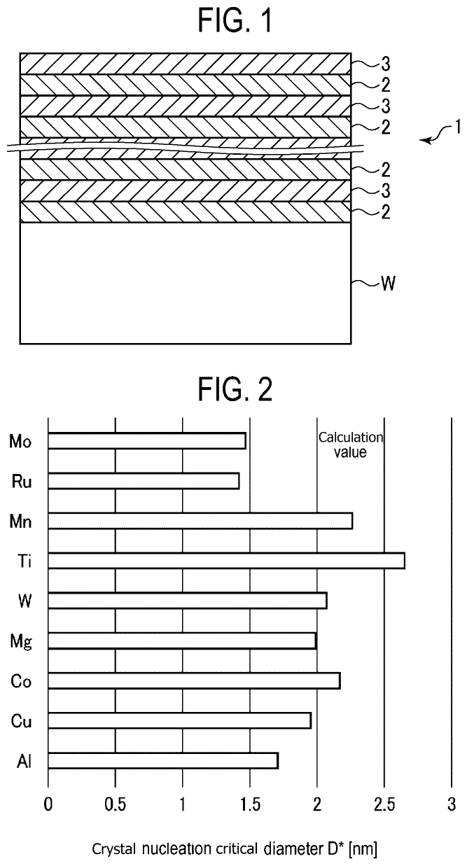

FIG. 1 is a cross-sectional view schematically illustrating a metal-containing film according to an embodiment. A metal-containing film 1 has a laminate structure in which a first metal-containing unit film 2 and a second metal-containing unit film 3 which differs from the first metal-containing unit film are laminated alternately, and is formed on a substrate W. Both the first metal-containing unit film 2 and the second metal-containing unit film 3 have a film thickness less than a crystal nucleation critical diameter. The metal-containing film 1 does not include a grain boundary. Examples of the substrate W include a semiconductor substrate and an FPD substrate.

When the radius of nuclei is less than a critical nuclear radius r*, the energy due to volume increase cannot exceed the surface energy, nucleation is not promoted, and no crystal nuclei are formed. However, when the radius of nuclei exceeds the critical nuclear radius r*, nucleation is promoted, and crystal nuclei are formed. That is, the critical nuclear radius r* is a critical crystal nucleus size at or above which crystal nuclei are formed, and may be rephrased as a crystal nucleation critical diameter. The diameter of the nuclei at that time is a crystal nucleation critical diameter D*. Therefore, by suppressing the film thicknesses of the first metal-containing unit film 2 and the second metal-containing unit film 3 to less than the crystal nucleation critical diameter D*, the diameter of the nuclei may become less than the crystal nucleation critical diameter D*, and theoretically, crystallization of the first metal-containing unit film 2 and the second metal-containing unit film 3 may be suppressed. As a result, the metal-containing film 1 may be a film that does not contain grain boundaries.

The critical nuclear radius r* may be calculated for each metal by a relational expression proportional to Tm/TΔmax by using the maximum degree of supercooling ΔTmax and the melting point Tm. The crystal nucleation critical diameter D* is twice the critical nuclear radius r* calculated in this way. The calculation values of the crystal nucleation critical diameters D* of main metals are illustrated in FIG. 2. As illustrated in FIG. 2, many metals have a calculated crystal nucleation critical diameters D* in the range of 1.4 to 2.6 nm, and crystallization can be suppressed by setting the film thicknesses of the first metal-containing unit film 2 and the second metal-containing unit film 3 to be less than these values.

As a method of forming the first metal-containing unit film 2 and the second metal-containing unit film 3 with such film thicknesses include PVD, general thin film forming techniques such as PVD, which is typified by sputtering, and ALD and CVD, which are chemical film forming methods using gas, may be used.

For the first metal-containing unit film 2 and the second metal-containing unit film 3, it is preferable to select a combination that has as little reactivity as possible, or a combination that has a two-phase coexistence relationship. When an interfacial reaction occurs between these layers and a chemical potential difference is created, diffusion (migration of atoms) occurs, which makes it easier to undergo a phase transition from a metastable state to a stable state, making it easier to crystallize.

The first metal-containing unit film 2 and the second metal-containing unit film 3 may be a metal nitride film or a metal film. Examples of combinations of the first metal-containing unit film 2 and the second metal-containing unit film 3 include a combination in which one of them is a metal nitride film and the other is a metal film, a combination in which both are metal nitride films, and a combination in which both are metal films.

An example of the metal nitride film constituting the first metal-containing unit film 2 or the second metal-containing unit film 3 may be one of TiN, NbN, VN, WN, TaN, MoN, and W₂N₃, and an example of the metal film may be one of Ru, Co, Ni, Mo, W, Al, Ti, V, Mn, Si, and Mg.

Preferred combinations of the first metal-containing unit film 2 and the second metal-containing unit film 3 may include the following.
Combination of metal nitride films
TiN—TaN, TiN—NbN, TiN—MoN, TiN—W₂N₃, TaN—NbN, TaN—W₂N₃
Combination of metal nitride film and metal film
TiN—W, TiN—Mo, TiN—Ru, TaN—W, TaN—Mo, TaN—Ru
Combination of metal films
Si—Al, W—Al, Mg—Al, W—Ti, V—Ti, Mg—Ti

The above preferred combinations have as little reactivity as possible or have a two-phase coexistence relationship, are difficult to cause diffusion (migration of atoms) due to interfacial reactions, and are difficult to crystallize.

However, even if a combination of the first metal-containing unit film 2 and the second metal-containing unit film 3 is reactive, it is possible to form a metal-containing film that does not contain grain boundaries. For example, the combination of Al—Ti is a combination in which Al and Ti have reactivity. In addition, since Al—Ti is a pure metal system, the bonding is metallic in nature and has a weak bond strength. Therefore, the combination of Al—Ti is a combination in which it is difficult to maintain an amorphous state, which is a metastable state. Even with such a combination, as a result of forming a metal-containing film with a laminate structure under the following conditions, it was possible to obtain a metal-containing film that actually did not contain grain boundaries.
Thickness of Al film: 1.6 nm (less than 1.7 nm, which is the calculation value of D*)
Thickness of Ti film: 0.8 nm (less than 2.7 nm, which is the calculation value of D*)
Film forming method: sputtering
Film thickness ratio (Al:Ti): 77:23, 66:34, 55:45
Total film thickness (target value): 35 nm

In addition, when producing a metal-containing film having an Al—Ti laminate structure by sputtering, Sample A in which the Al film had a thickness of 1.6 nm, which is less than 1.7 nm, and Sample B in which an Al film had a thickness of 1.8 nm, which is 1.7 nm or more, were compared. In film formation, the film thickness ratio of Al and Ti was set to 2:1, and the total film thickness was set to 100 nm.

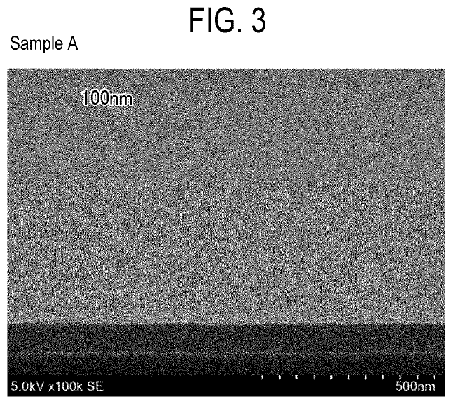

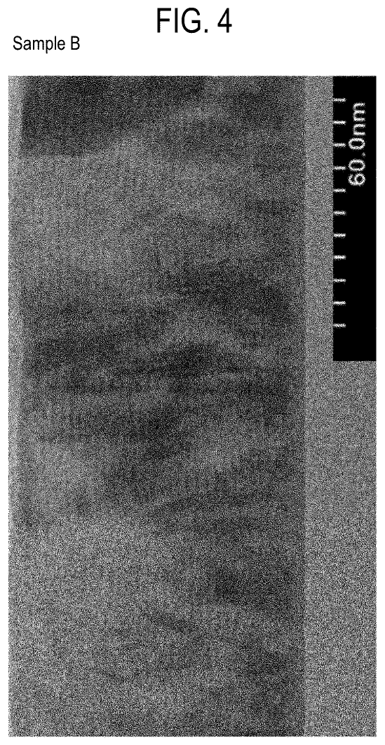

As a result, in Sample A where the thickness of the Al film was less than 1.7 nm, which is the calculation value of D*, the film was in an amorphous state without grain boundaries, as shown in the SEM photograph of FIG. 3, but in sample B in which the thickness of the Al film was equal to or more 1.7 nm, which is the calculation value of D*, crystallization was observed as shown in the SEM photograph of FIG. 4.

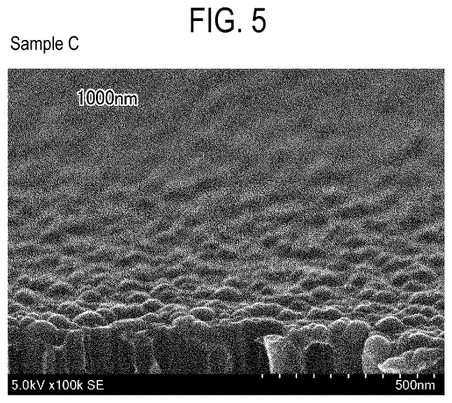

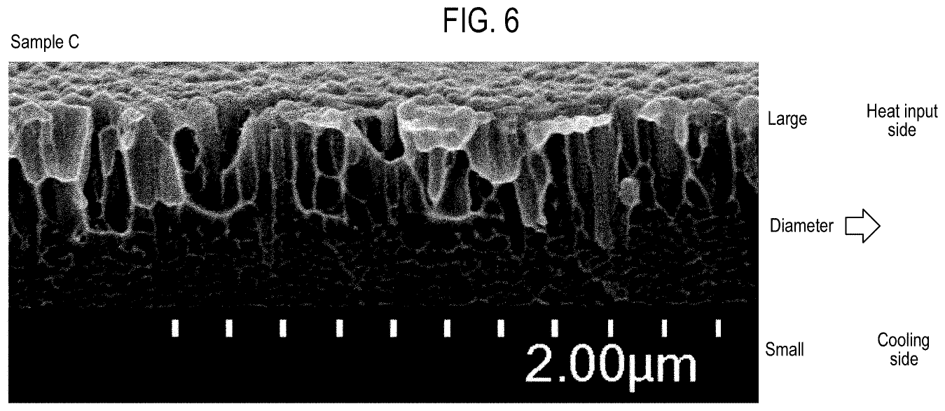

Next, Sample C was manufactured under the same conditions as Sample A except that the total film thickness was 1,000 nm. As a result, crystallization occurred as shown in the SEM photograph of FIG. 5. FIG. 6 is an SEM photograph showing an enlarged cross section of Sample C in which the crystal grain size on the substrate side is small, whereas the crystal grain size on the surface side is large. From this, it is thought that the crystallization occurred because during sputtering-based film formation, heat was input from the surface side, and as the film thickness became thicker, the effect of heat input became greater. In addition, it is thought that the reason why the crystal grain size differs between the substrate side and the surface side because the substrate side is the cooling side, the surface side is the heat input side, and there is a difference in the degree of supercooling.

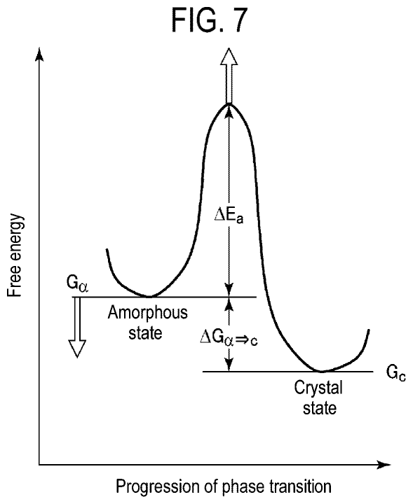

In this way, the first metal-containing unit film 2 and the second metal-containing unit film 3 may be crystallized by heat input even if the film thickness is less than the crystal nucleation critical diameter D*. FIG. 7 is a diagram showing a transition of free energy during phase transition from an amorphous state, which is a metastable state, to a crystalline state, which is a stable state. As shown in this figure, activation energy ΔEa is required for phase transition from the amorphous state, which is a metastable state, to the crystalline state, which is a stable state. However, when there is heat input and the activation barrier ΔEa is overcome by the heat input, the crystalline state is reached. Therefore, in order to maintain the amorphous state without crystallization even when there is heat input, it is necessary to reduce the free energy Gα of the amorphous state to make the amorphous state more stable, to increase the activation energy ΔEa to raise the phase transition barrier, or both.

Since an amorphous substance is a supercooled liquid that solidifies as it is, it is thought that as the maximum degree of supercooling is greater, it is easier to maintain a metastable amorphous state. That is, it is thought that as the maximum degree of supercooling is greater, Gα becomes smaller, and the amorphous state becomes more stable. Therefore, in order to stabilize the amorphous state, it is effective to add an element that increases the degree of supercooling.

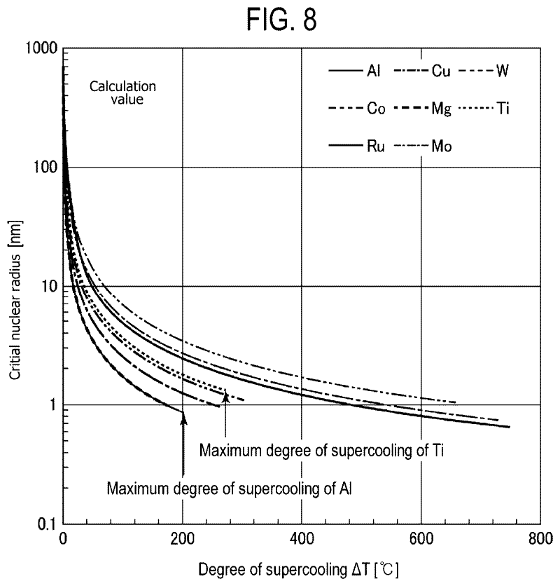

FIG. 8 is a diagram showing relationships (calculation values) between the degrees of supercooling and the critical nuclear radii r* of various metals, in which the right end of the degree of supercooling curve for each metal is the maximum degree of supercooling. From this figure, it can be seen that both Al and Ti have a small maximum degree of supercooling and are materials that are difficult to maintain in an amorphous state.

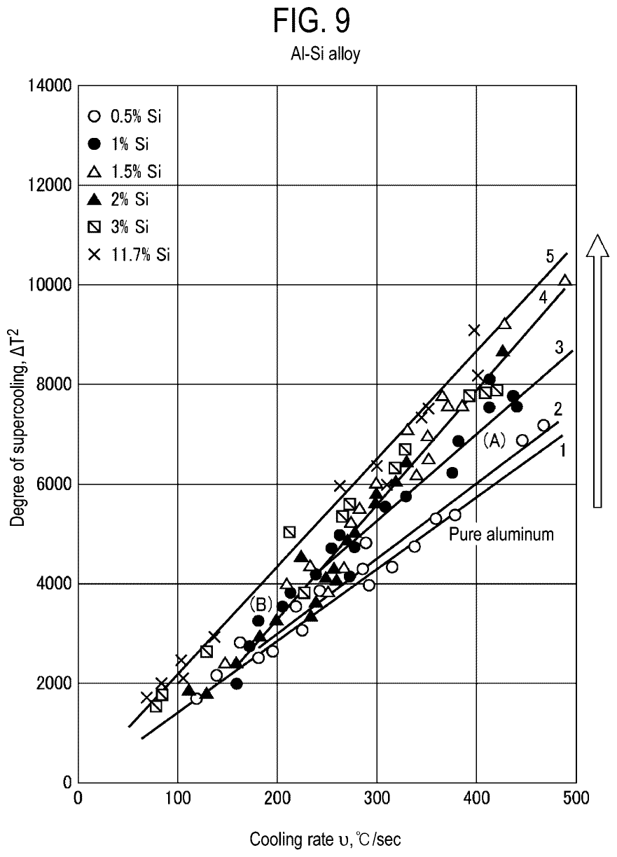

Therefore, when producing a metal-containing film with an Al—Ti laminate structure, an attempt was made to stabilize the amorphous state by adding an element that increases the degree of supercooling to the Al film. FIG. 9 is a diagram showing relationships between the degrees of supercooling and the cooling rates in Al—Si alloys (Source: Ichikawa et al., Castings vol. 46 (1973), 1, 25, FIG. 8). This figure shows that Si is an element that increases the degree of supercooling of pure Al.

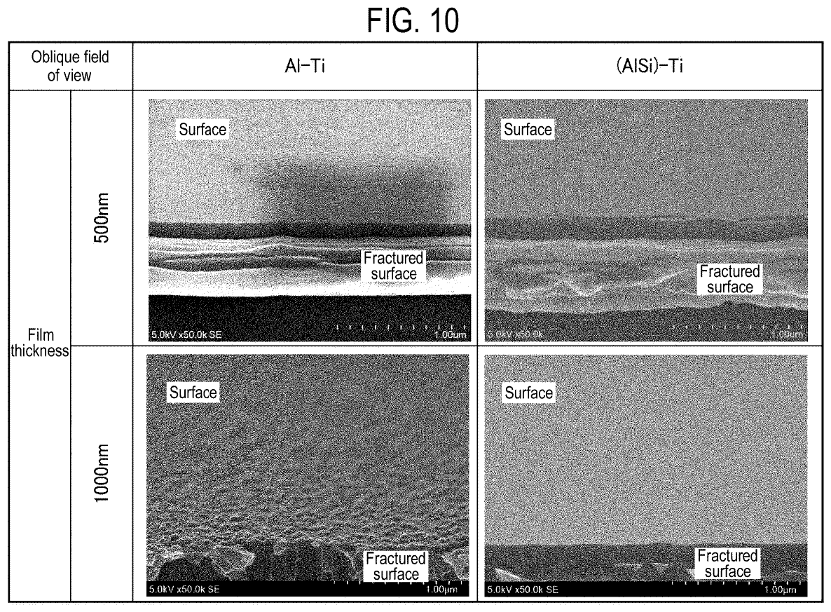

Actually, a metal-containing film having an Al—Ti laminate structure and a metal-containing film having an (AlSi)—Ti laminate structure were formed by sputtering to thicknesses of 500 nm and 1,000 nm. The amount of Si added to the AlSi film was 6 at %, and the thicknesses of the Al film and the AlSi film were 1.6 nm. FIG. 10 shows SEM photographs of these films. As is clear from the SEM photographs, in the Al—Ti laminate structures, crystallization did not occur at a film thickness of 500 nm, but crystallization occurred at a film thickness of 1,000 nm. In contrast, in the (AlSi)—Ti laminate structures, no crystallization occurred even at the film thickness of 1,000 nm. From this, it is thought that by adding Si to Al and increasing the degree of supercooling of pure Al, Gα became smaller and it was possible to maintain the amorphous state, which is a metastable stable. The addition of elements itself leads to an increase in entropy, which is advantageous for reducing Gα.

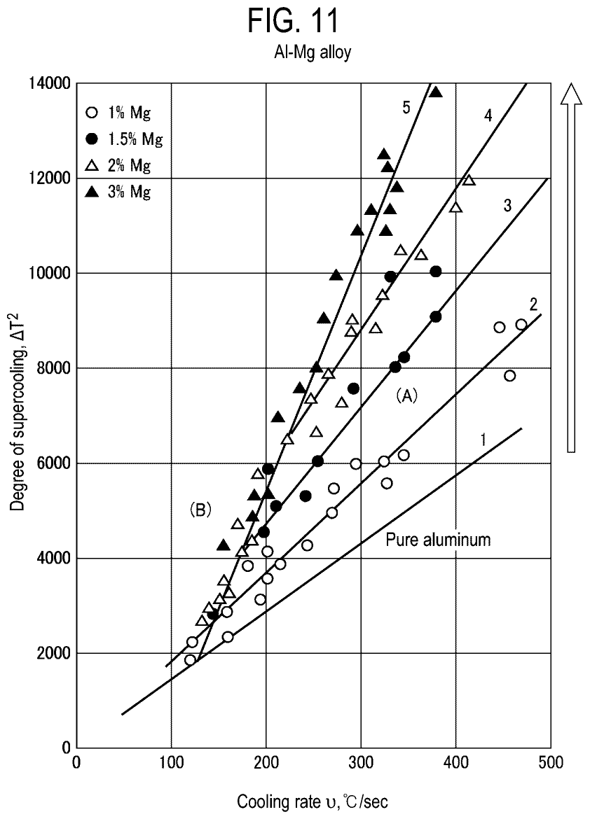

In addition to Si, Mg is also known as an element that increases the degree of supercooling of an Al film. FIG. 11 is a diagram showing relationships between the degrees of supercooling and the cooling rates in Al—Mg alloys (Source: Ichikawa et al., Castings vol. 46 (1973), 1, 25, FIG. 4). From this, it can be seen that Mg can be an additive element that increases the degree of supercooling of pure Al.

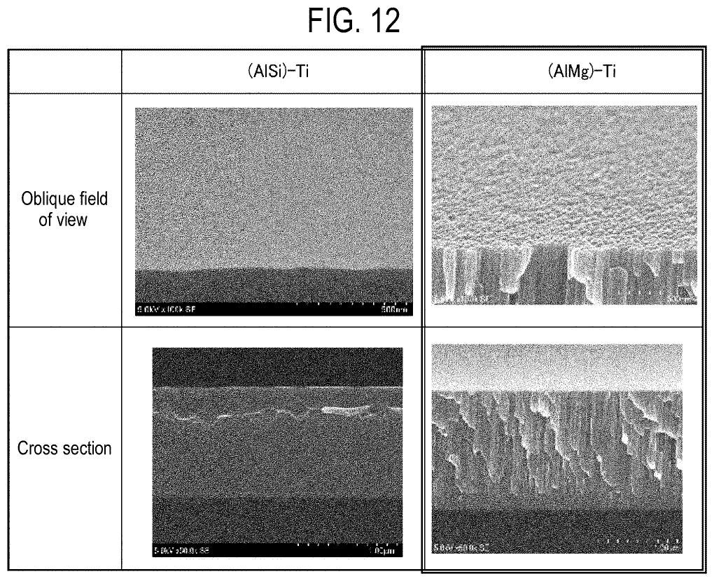

In addition, a metal-containing film having an (AlMg)—Ti laminate structure was actually formed with a thickness of 1,000 nm by sputtering. The amount of Mg added to the AlMg film was 6 at %, and the film thickness was 1,000 nm. FIG. 12 shows SEM photographs of metal-containing films having the above-mentioned (AlSi)—Ti laminate structure and metal-containing films having the (AlMg)—Ti laminate structure. As is clear from the SEM photographs, the (AlSi)—Ti laminate structure did not crystallize at the thickness of 1,000 nm, whereas the (AlMg)—Ti laminate structure crystallized at the thickness of 1,000 nm.

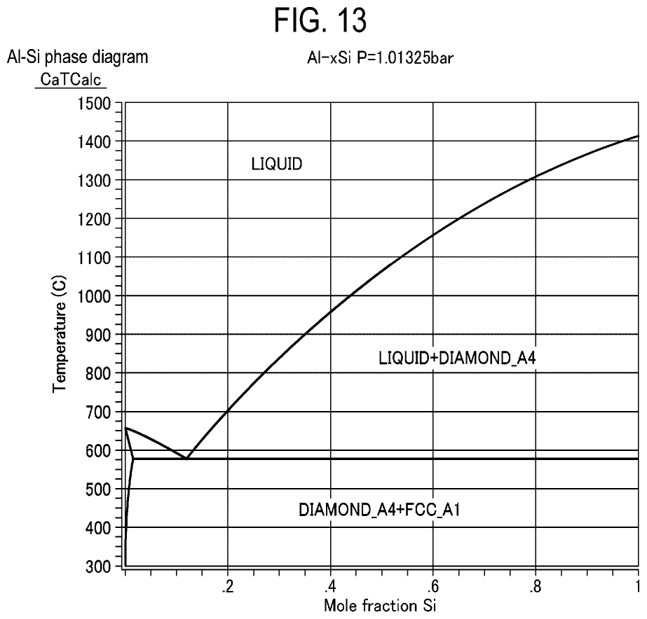

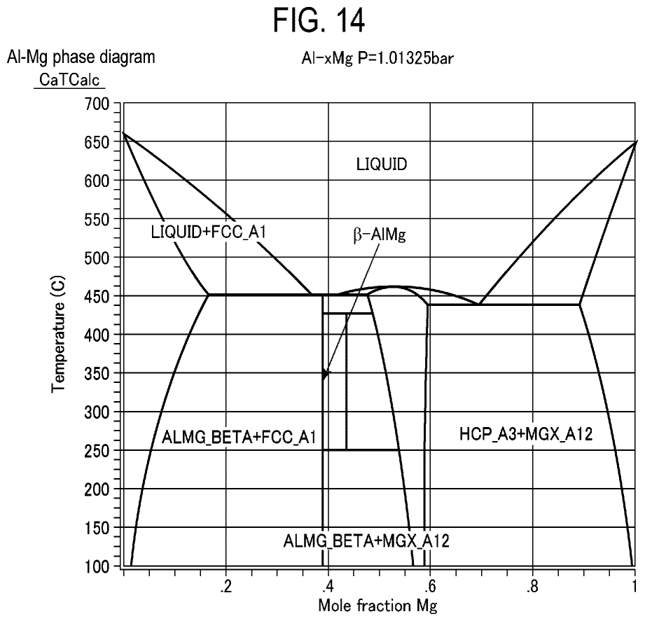

Thus, although both Si and Mg are additive elements that increase the degree of supercooling of Al, Mg did not have the effect of stabilizing the amorphous state. This difference was investigated based on phase diagrams. FIG. 13 is an Al—Si phase diagram, and FIG. 14 is an Al—Mg phase diagram. As is clear from these figures, Al—Si is a phase-separated system (eutectic system), whereas Al—Mg is an intermetallic compound-forming system. In other words, Si and Mg have very different interactions with Al. In Al—Si, Al and Si repel each other and separate into a phase mainly composed of Al and a phase mainly composed of Si, whereas in Al—Mg, Al and Mg attract each other and are easily ordered as Al—Mg—Al.

Such interactions can be understood by the interaction parameter of the mixing enthalpy of a binary system (Nishizawa, Sudo et al., Metallography, Maruzen (published Aug. 31, 1972)). The mixing enthalpy ⁰Hₘᵢₓ at 0K of the binary system of pure substances A and B may be expressed by the following Equation 1. In Equation 1, HA and OHB are the enthalpies of pure substances A and B at 0K, X_{B} is the atomic fraction of pure substance B, and ⁰Ω_{AB} is an interaction parameter. The interaction parameter ⁰Ω_{AB} is expressed by the following Equation 2. In Equation 2, N is the total number of atoms including A and B, z is the number of coordinations, and e_{AB}, e_{AA}, and e_{BB} are the bond energies of A-B, A-A, and B-B, respectively.

$$\begin{matrix}[ Equation 1 ] & \\ {}_{}^{0} {H}_{mix}^{} = {}_{}^{0} {H}_{A}^{} ( 1 - {X}_{B} ) + {}_{}^{0} {H}_{B}^{} {X}_{B} + {}_{}^{0} {Ω}_{AB}^{} ( 1 - {X}_{B} ) {X}_{B} & ( 1 )\end{matrix}$$

$$\begin{matrix}[ Equation 2 ] & \\ {}_{}^{0} {Ω}_{AB}^{} = Nz ( {e}_{AB} - \frac{{e}_{AA} + {e}_{BB}}{2} ) & ( 2 )\end{matrix}$$

The physical meaning of the value of the interaction parameter ⁰Ω_{AB} is as follows.

$${}_{}^{0} {Ω}_{AB}^{} > 0 : \qquad ( 1 )$$

In this case, e_{AB}>(e_{AA}+e_{BB})/2, and since the A-B pair has energy higher than the average energy of the A-A pair and the B-B pair and is unstable, A and B are repulsive, meaning that they tend to separate into a phase containing A as the main component and a phase containing B as the main component. Therefore, it becomes a combination that tends to form an amorphous state. This is the case for the above-mentioned Al—Si system.

$${}_{}^{0} {Ω}_{AB}^{} < 0 : \qquad ( 2 )$$

In this case, e_{AB}<(e_{AA}+e_{BB})/2, and since the A-B pair has energy lower than the average energy of the A-A pair and the B-B pair and is stable, A and B tend to attract each other, which means that ordering along with A-B-A-B is likely to occur. Therefore, it becomes less likely to become amorphous. This is the case for the above-mentioned Al—Mg system.

$${}_{}^{0} {Ω}_{AB}^{} = 0 : \qquad ( 2 )$$

In this case, e_{AB}=(e_{AA}+e_{BB})/2, and since the energy of the A-B pair is equal to the average energy of the A-A pair and the B-B pair, there is no interaction between A and B, and the arrangement of A and B is disordered. Such a solid solution is called an ideal solution, and is a combination that tends to form an amorphous state.

It is thought that the mixing enthalpy ⁰Hₘᵢₓ of the above binary system is related to the activation energy ΔEa during phase transition from an amorphous state to a crystalline state occurs and ΔEa changes depending on the value (positive or negative) of the interaction parameter ⁰Ω_{AB}. The difference in behavior when Si and Mg are added to Al as described above may be explained by the difference in ΔEa depending on whether ⁰Ω_{AB} is positive or negative. That is, since ⁰Ω_{AB}>0 in the Al—Si system, the added Si repels the parent phase Al, increasing ΔEa. On the other hand, since ⁰Ω_{AB}<0 in the Al—Mg system, ΔEa decreases as the added Mg combines with Al, which is the parent phase, and becomes ordered.

As described above, by adding an element that increases the degree of supercooling to either or both of the first metal-containing unit film 2 and the second metal-containing unit film 3, the amorphous state can be stabilized by lowering Gα, and crystallization due to heat input can be suppressed. Furthermore, as the element that increases the degree of supercooling, it is preferable to select an element such that the interaction parameter ⁰Ω_{AB} between the element and the parent phase satisfies the following: ⁰Ω_{AB}≥0.

Such an additive element that increases the degree of supercooling is effective when the first metal-containing unit film 2 and the second metal-containing unit film 3 are metal films, and an appropriate material may be selected depending on these materials. For example, when the material is Al in addition to the fact that Si is suitable as an additive element as described above, when the material is Ru, Ir, Pd, Ni, Co, and Mn are suitable as additive elements, and when the material is Co Ni, Cu, Pd, and Ru are suitable. In addition, when the material is W, Mo, Ta, Nb, Ti, and Mn are suitable as additive elements; when the material is Mo, W, Ta, Nb, Ti, and Mn are suitable, and when the material is Ti, Zr, Hf, V, W, Mo, Nb, and Ta are suitable, and when the material is Mn, Ru, Fe, Mo, and W are suitable.

### <How Metal-Containing Film Having Laminate Structure was Achieved>

Next, a description will be given of how the metal-containing film having laminate structure in the present embodiment was achieved.

Films containing metals such as W, Cu, TiN, and TaN are used in semiconductor devices for various purposes, such as wiring metals for fine wiring, pillar- or cylinder-structured electrodes for capacitors, barrier films, and metal hard masks. Such metal-containing films generally have a crystalline structure, and crystal grain boundaries may cause matters in a semiconductor device itself and its producing process.

For example, in fine wiring, wiring resistance increases due to grain boundary scattering and interface scattering due to irregularities based on grain boundaries. In addition, in metal hard masks used for microfabrication, when grain boundaries exist, the shapes of the grain boundary portions may be transferred to the workpieces as they are, or deformation (wiggling) occurs due to film stress caused by grain boundary slippage. Further, in fine wiring, stress concentration due to grain boundary slippage causes twisting, which may increase interfacial resistance and induce misalignment due to interference between adjacent wires. In pillar- or cylinder-structured electrodes, mechanical strength decreases due to grain boundary slippage, and plastic deformation such as leaning (collapse or destruction) occurs during the producing process due to shear stress being applied to grain boundaries. In addition, barrier films are used as diffusion barriers for halogen-based impurities or the like, but when grain boundaries are present, the barrier properties thereof are significantly reduced due to bypass diffusion via the grain boundaries.

On the other hand, the present embodiment obtains a metal-containing film 1 that has a laminate structure of a first metal-containing unit film 2 and a second metal-containing unit film 3, and that does not contain grain boundaries. Therefore, there is no increase in resistance due to grain boundary scattering or interfacial scattering due to unevenness based on grain boundaries, and there are advantages in that it is easy to trace a shape during processing and it is easy to produce a flat cross section. Furthermore, stress concentration or strength reduction due to grain boundary slippage does not occur, and bypass diffusion via grain boundaries does not occur. Therefore, the metal-containing film having a laminate structure of the present embodiment is suitable for applications such as wiring metals for fine wiring, pillar- or cylinder-structured electrodes, barrier films, metal hard masks, and the like.

As metal-containing films, which do not contain grain boundaries, amorphous structures and single crystals called amorphous metals and glass metals have been conventionally known. However, conventional metal-containing films having an amorphous structure are often alloyed by combining multiple metals, which has little freedom in combining metal elements, which poses a major constraint on the performance of semiconductors or the producing process of semiconductor devices. In addition, in order to obtain a single crystal, a high temperature process is required, the steps are limited, and the process is complicated, making production difficult. Furthermore, the materials that can be grown into single crystals are also limited.

On the other hand, in the present embodiment, since it is only necessary to form a laminate structure of the first metal-containing unit film 2 and the second metal-containing unit film 3, a metal-containing film can be manufactured by combining existing film forming processes and there is no difficulty in production. Furthermore, there is a high degree of freedom in material selection, and the combination of materials for the first metal-containing unit film 2 and the second metal-containing unit film 3 can be selected depending on the required performance of devices or requests and constraints from a process. Furthermore, it may be possible to obtain new functional materials simply by combining existing processes.

### <Application of Metal-Containing Film>

Next, the applications of the metal-containing film according to the present embodiment will be described in more detail.

The applications of the metal-containing film of the present embodiment may include wiring metals for fine wiring, barrier films, pillar- or cylinder-structured electrodes, metal hard masks, and the like.

The wiring metal using the metal-containing film according to the present embodiment may be used, for example, as a substitute for a W film, Cu film, and TiN film used for existing fine wiring.

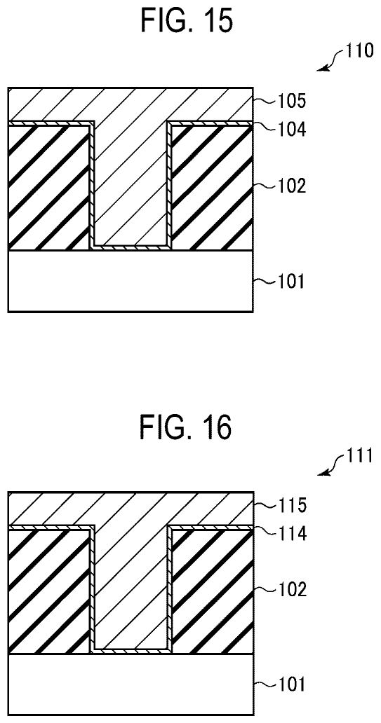

FIG. 15 is a cross-sectional view illustrating an example of fine wiring in which a metal-containing film of an embodiment is applied to a wiring metal. In the fine wiring 110 illustrated in FIG. 15, an insulating film 102 having a recess such as a trench or hole is formed on a substrate 101 having a bottom structure (not illustrated), and a metal-containing film 105, which serves as a wiring metal, is embedded in the recess through a barrier film 104. When the metal-containing film forming the wiring metal has grain boundaries, as described above, the wiring resistance increases due to grain boundary scattering and interface scattering due to unevenness based on the grain boundaries, or twisting occurs due to grain boundary slippage. However, since the metal-containing film 105 of the present embodiment does not contain grain boundaries, such a matter does not occur.

An appropriate combination of a first metal-containing unit film and a second metal-containing unit film forming the metal-containing film 105, which serves as a wiring metal, may be selected depending on the required characteristics such as a resistance value. For example, as described above, any of a combination in which one is a metal nitride film and the other is a metal film, a combination in which both are metal nitride films, and a combination in which both are metal films may be used. A typical example of a combination is a combination of a TiN film (1 to 2 nm thick) and a WN film (1 to 2 nm thick). In addition, examples of the combinations also include a TiN film (1 to 2 nm thick) and a Ru film (1.3 nm or less thick), a TiN film (1 to 2 nm thick) and a Mn film (2.2 nm or less thick), a TiN film (1 to 2 nm thick) and an Al film (1.6 nm or less thick), and a TiN film (1 to 2 nm thick) and a Ti film (2.6 nm or less thick).

A barrier film using a metal-containing film according to an embodiment may be used as a substitute for, for example, a TaN film or a TiN film used as an existing barrier film.

FIG. 16 is a cross-sectional view illustrating an example of a fine wiring structure in which a metal film of an embodiment is applied to a barrier film. In a fine wiring structure 111 in FIG. 16, in an insulating film 102 having a recess such as a trench or a hole is formed on a substrate 101 having a bottom structure (not illustrated) similar to that in FIG. 15, a metal-containing film 114 of the present embodiment is formed as a barrier film in the recess, and fine wiring 115 is embedded in the recess. When the metal-containing film forming the barrier film has grain boundaries, as described above, the presence of grain boundaries significantly reduces the barrier properties of the barrier film due to bypass diffusion through the grain boundaries, but such a matter does not occur in the metal-containing film 114 of the present embodiment, which does not contain grain boundaries.

An appropriate combination of the first metal-containing unit film and the second metal-containing unit film forming the metal-containing film 114 serving as a barrier film may be selected depending on the required barrier properties. For example, as described above, any of a combination in which one is a metal nitride film and the other is a metal film, a combination in which both are metal nitride films, and a combination in which both are metal films may be used. A typical example of a combination is a combination of a TiN film (1 nm thick) and a WN film, a VN film, or a NbN film (all 1 nm thick).

A pillar- or cylinder-structured electrode using a metal-containing film according to an embodiment may be used, for example, as a substitute for a TiN film or the like used in an existing electrode.

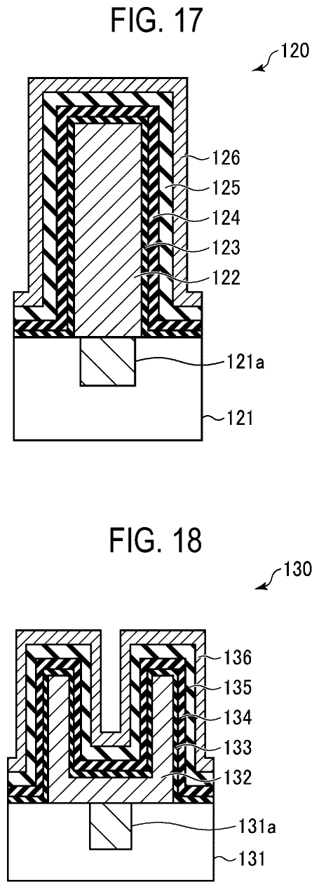

FIG. 17 is a cross-sectional view illustrating an example of a capacitor in which a metal-containing film of an embodiment is applied to a pillar-structured electrode. In the present example, a lower electrode of a capacitor 120 is an example of a pillar-structured electrode, and a metal-containing film 122 of the present embodiment, which serves as a pillar-structured lower electrode, is formed on a contact 121a formed on a substrate 121. For example, a first TiO₂ film 123, a ZrO₂ film 124, and a second TiO₂ film 125 are formed as dielectric films on the metal-containing film 122, and an upper electrode 126 is formed on the second TiO₂ film 125. However, the materials and numbers of layers of dielectric films are not limited to this example. In the process of producing the capacitor illustrated in FIG. 17, an insulating film, which has supported the lower pillar-structured electrode is removed, the lower electrode is made to stand on its own, and then a dielectric film or the like are formed. At this time, when grain boundaries are present in the lower electrode, mechanical strength may be reduced due to grain boundary slippage, and plastic deformation such as leaning (collapse or destruction) may occur due to shear stress being applied to the grain boundaries. In contrast, in the present example, since the metal-containing film 122 of the present embodiment, which does not contain grain boundaries, is used as a pillar-structured lower electrode, there is no decrease in mechanical strength due to grain boundary slippage, and plastic deformation such as leaning due to decrease in strength is unlikely to occur.

FIG. 18 is a cross-sectional view illustrating an example of a capacitor in which a metal-containing film of an embodiment is applied to a cylinder-structured electrode. In the present example, a lower electrode of a capacitor 130 is an example of a cylinder-structured electrode, and a metal-containing film 132 of the present embodiment, which serves as a cylinder-structured lower electrode, is formed on a contact 131a formed on a substrate 131. For example, a first TiO₂ film 133, a ZrO₂ film 134, and a second TiO₂ film 135 are formed as dielectric films on the metal-containing film 132, and an upper electrode 136 is formed on the second TiO₂ film 135. However, the materials and numbers of dielectric films are not limited to this example. In the process of producing the capacitor illustrated in FIG. 18, an insulating film, which has supported the lower cylinder-structured electrode, is removed to make the lower electrode stand on its own, and then a dielectric film or the like is formed. Even in the case of the cylinder structure, the presence of grain boundaries may cause plastic deformation such as leaning (collapse or destruction), but since the metal-containing film 132, which does not contain grain boundaries, is used as the lower electrode, there is no decrease in mechanical strength due to slippage, and plastic deformation such as leaning due to decrease in strength is unlikely to occur.

An appropriate combination of a first metal-containing unit film and a second metal-containing unit film forming a metal-containing film 122 or 132, which serves as a filler- or cylinder-structured electrode, may be selected depending on the required characteristics such as a resistance value. For example, as described above, any of a combination in which one is a metal nitride film and the other is a metal film, a combination in which both are metal nitride films, and a combination in which both are metal films may be used. A typical example of a combination is a combination of a TiN film (1 nm to 2 nm thick) and a WN film, a VN film, or a NbN film (all 1 nm to 2 nm thick).

A metal hard mask using a metal-containing film according to an embodiment may be used, for example, as a substitute for a TiN film used as a metal hard mask.

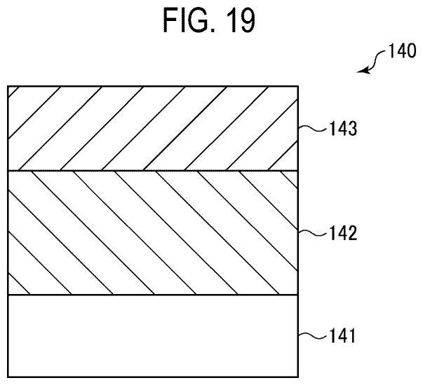

FIG. 19 is a cross-sectional view illustrating an example of a structure in which a metal-containing film of an embodiment is applied to a hard mask. The structure 140 of the present example includes an etching target film 142 formed on a substrate 141, and a metal-containing film 143 of the present embodiment serving as a metal hard mask formed on the etching target film. The etching target film 142 is not particularly limited, but examples thereof include a tungsten film, a GeSbTe (GST) film, a poly-Si film, a carbon film, a SiO₂ film, a SiON film, and the like. In addition, the etching target film 142 may be a laminated film in which a plurality of films are laminated. When a metal-containing film forming a metal hard mask has grain boundaries, as described above, the shapes of grain boundary portions may be transferred as they are to the etching target film 142, which is the workpiece, or deformation (wiggling) may occur due to film stress due to grain boundary slippage. In contrast, in the metal-containing film 143 of the present example, which does not contain grain boundaries, such matters do not occur.

As the first metal-containing unit film and the second metal-containing unit film forming a metal-containing film 143 serving as a hard mask, as described above, any of a combination in which one is a metal nitride film and the other is a metal film, a combination in which both are metal nitride films, and a combination in which both are metal films may be used. Among them, an appropriate combination may be selected depending on the material of the etching target film 142.

### <Method for Producing Metal-Containing Film>

Next, a method for producing a metal-containing film according to an embodiment will be described.

A film forming method according to the present embodiment alternately performs a process of forming a first metal-containing unit film 2 with a thickness less than a crystal nucleation critical diameter and a process of forming a second metal-containing unit film 3, which differs from the first metal-containing unit film 2, with a thickness less than the crystal nucleation critical diameter, thereby producing a metal-containing film 1 having a laminate structure that does not contain grain boundaries.

The first metal-containing unit film 2 and the second metal-containing unit film 3 may be formed by using general thin film forming techniques, such as PVD, typically sputtering, and ALD and CVD, which are chemical film-forming methods using gas. These may be used in combination. For example, the first metal-containing unit film 2 and the second metal-containing unit film 3 may be formed by a combination of PVD and ALD, a combination of PVD and CVD, or a combination of ALD and CVD. These will be described below.

### [Film Formation by PVD]

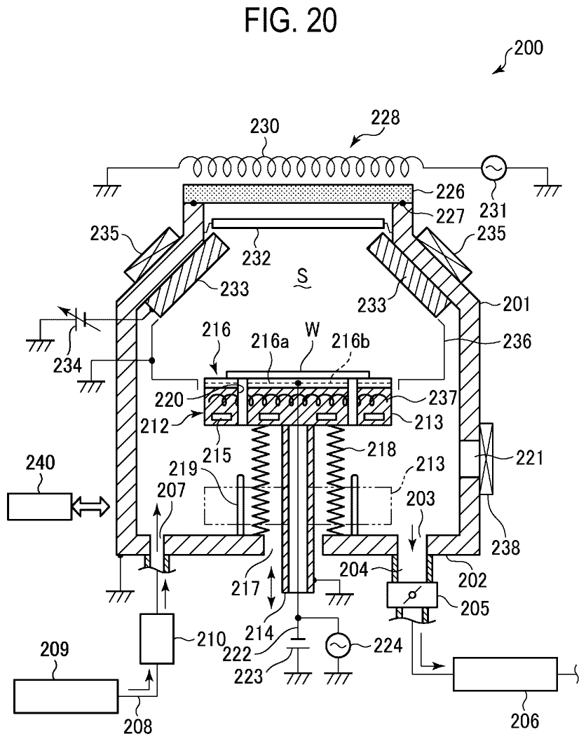

FIG. 20 is a cross-sectional view illustrating an example of a plasma sputtering apparatus for performing film formation by PVD.

The apparatus in FIG. 20 is an ICP type plasma sputtering apparatus, which is a type of ionization PVD apparatus.

As illustrated in FIG. 20, this plasma sputtering apparatus 200 has a grounded processing container 201 made of metal, and the bottom portion 202 of the processing container 201 is provided with an exhaust port 203 and a gas inlet 207. An exhaust pipe 204 is connected to the exhaust port 203, and a throttle valve 205 and a vacuum pump 206 for adjusting pressure are connected to the exhaust pipe 204. In addition, a gas supply pipe 208 is connected to the gas inlet 207, and a gas source 209 is connected to the gas supply pipe 208 to supply a plasma excitation gas such as Ar gas and other necessary gases such as N₂ gas. A gas controller 210 including a gas flow rate controller, a valve, and the like is interposed in the gas supply pipe 208.

A placement mechanism 212 on which a substrate W is placed is provided inside the processing container 201. This placement mechanism 212 has a stage 213 molded in a disk shape and a hollow cylindrical column 214 that supports this stage 213. The stage 213 is made of a conductive material and is grounded via the column 214. A cooling jacket 215 is provided inside the stage 213, into which a coolant is supplied to cool the stage. In the stage 213, a resistance heater 237 coated with an insulating material is embedded on the cooling jacket 215. By controlling the supply of coolant to the cooling jacket 215 and the supply of power to the resistance heater 237, the temperature of a substrate can be controlled to a predetermined temperature.

On the top surface side of the stage 213, an electrostatic chuck 216 configured to electrostatically attract a substrate W is provided, wherein the electrostatic chuck is constructed by embedding an electrode 216b in a dielectric member 216a. The lower portion of the column 214 penetrates an insertion hole 217 formed in the central portion of the bottom portion 202 of the processing container 201 and extends downward. The column 214 is configured to be raised and lowered by a lifting mechanism (not illustrated), whereby the entire placement mechanism 212 is raised and lowered.

An extendable metal bellows 218 is provided to surround the column 214. The upper end of the metal bellows 218 is bonded to the bottom surface of the stage 213, and the lower end is bonded to the top surface of the bottom portion 202 of the processing container 201 to allow the placement mechanism 212 to be raised and lowered while maintaining airtightness inside the processing container 201.

On the bottom portion 202, for example, three (only two are illustrated) support pins 219 are vertically provided upward. Pin insertion holes 220 corresponding to the support pins 219 are formed in the stage 213, and when the stage 213 is lowered, a substrate W is received at the upper ends of the support pins 219 passing through the pin insertion holes 220 so that the substrate W can be transferred to and from a transfer arm (not illustrated) that enters from the outside. A loading/unloading port 221 is provided in the lower side wall of the processing container 201 to allow the transfer arm to enter the processing container therethrough, and a gate valve 238 configured to be openable and closable is provided in the loading/unloading port 221.

A chuck power source 223 is connected to the electrode 216b of the above-described electrostatic chuck 216 via a power feeding line 222, and by applying a DC voltage from the chuck power source 223 to the electrode 216b, the substrate W is attracted and held by an electrostatic force. In addition, a radio-frequency (RF) power source 224 for bias is connected to the power feeding line 222, and RF power for bias is supplied to the electrode 216b of the electrostatic chuck 216 via the power feeding line 222, so that bias power is applied to the substrate 10. The frequency of this RF power is preferably 400 kHz to 60 MHz, for example, 13.56 MHz.

On the other hand, a transmission plate 226 made of a dielectric material is airtightly provided on the ceiling of the processing container 201 with a sealing member 227 interposed therebetween. A plasma generation source 228 is provided above the transmission plate 226 to generate plasma in the processing space S in the processing container 201 by plasmarizing the plasma excitation gas.

The plasma generating source 228 includes an induction coil 230 provided to correspond to the transmission plate 226, and, for example, an RF power source 231 of 13.56 MHz for plasma generation is connected to the induction coil 230, so that RF power is introduced into the processing space S through the above-described transmission plate to form an induced electric field.

Immediately below the transmission plate 226, a baffle plate 232 made of metal is provided for diffusing the introduced RF power. A target 233 having, for example, an inwardly inclined cross section is provided below the baffle plate 232 to surround the upper side of the processing space S. The target 233 is made of the material of a film to be formed. When forming both the first metal-containing unit film 2 and the second metal-containing unit film 3, a plurality of targets 233 may be provided to correspond to these materials, respectively. In addition, co-sputtering using a plurality of targets may be performed. A variable voltage DC power source 234 for the target is connected to the target 233, which applies DC power for attracting Ar ions. An AC power source may be used instead of the DC power source.

In addition, a magnet 235 is provided on the outer peripheral side of the target 233. The target 233 is sputtered by Ar ions in the plasma, particles are emitted from the target 233, and most of the particles are ionized when passing through the plasma.

Under the target 233, a cylindrical protective cover member 236 is provided to surround the processing space S. This protective cover member 236 is grounded. The inner end portion of the protective cover member 236 is provided to surround the outer peripheral side of the stage 213.

Each component of the plasma sputtering apparatus 200 is controlled by a controller 240. The controller 240 includes a main controller including a computer (CPU) that controls each component, an input device, an output device, a display device, and a storage device. The storage device stores parameters for various processes to be executed by the plasma sputtering apparatus 200. In addition, the storage device includes a storage medium in which the programs for controlling the processes to be executed by the plasma sputtering apparatus 200, that is, processing recipes, are stored. The main controller calls a predetermined processing recipe stored in the storage medium, and causes the plasma sputtering apparatus 200 to execute a predetermined process, based on the processing recipe.

In the plasma sputtering apparatus 200 configured as described above, a substrate W is loaded into the processing chamber 201, placed on the stage 213, and adsorbed by the electrostatic chuck 216, and the following operations are controlled by the controller 240. At this time, the temperature of the stage 213 is controlled by controlling the supply of the coolant to the cooling jacket 215 and the power feeding to the resistance heater 237 based on the temperature detected by a thermocouple (not illustrated).

First, the interior of the processing container 201 is maintained at a predetermined degree of vacuum by controlling the throttle valve 205 while causing Ar gas to flow into the processing container 201, which is brought into a predetermined vacuum state by operating the vacuum pump 206, at a predetermined flow rate by operating the gas controller 210. Thereafter, DC power is applied to the target 233 from the variable voltage DC power source 234, and RF power (plasma power) is supplied to the induction coil 230 from the RF power source 231 of the plasma generation source 228. On the other hand, RF power for bias is supplied to the electrode 216b of the electrostatic chuck 216 from the RF power source 224 for bias.

As a result, inside the processing container 201, argon plasma is formed by the RF power supplied to the induction coil 230 to generate argon ions, and these ions are attracted to the DC voltage applied to the target 233 and collide with the target 233, which is sputtered to emit particles. At this time, the amount of released particles is optimally controlled by the DC voltage applied to the target 233.

Most of the particles from the sputtered target 233 are ionized and scattered downward while passing through the plasma.

When entering the region of an ion sheath having a thickness of several millimeters formed on the surface of the substrate W by the RF power for bias applied to the electrode 216b of the electrostatic chuck 216 from the RF power source 224 for bias, the ions are attracted to the substrate W side to be accelerated with strong directivity and deposited on the substrate W. As a result, a desired film is formed on the substrate W.

When forming both the first metal-containing unit film 2 and the second metal-containing unit film 3 by sputtering, these films may be formed successively by simply switching targets in the plasma sputtering apparatus 200 to form a metal-containing film 1.

After the film formation is completed, the interior of the processing container 201 is purged, the stage 213 is lowered, the gate valve 238 is open, and the substrate W is unloaded.

### [Film Formation by ALD or CVD]

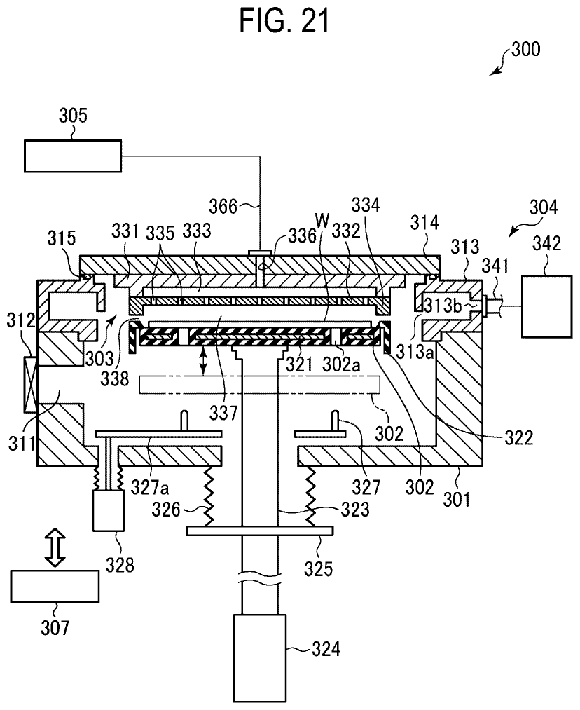

FIG. 21 is a cross-sectional view illustrating an example of a film forming apparatus for performing film formation by ALD or CVD.

As illustrated in FIG. 21, a film forming apparatus 300 includes a processing container 301, a susceptor 302, a shower head 303, an exhauster 304, a gas supply mechanism 305, and a controller 307.

The processing container 301 is made of metal and has a substantially cylindrical shape. A loading/unloading port 311 for loading/unloading a substrate W is formed in the side wall of the processing container 301, and the loading/unloading port 311 is configured to be opened and closed by a gate valve 312. An annular exhaust duct 313 having a rectangular cross section is provided on the main body of the processing container 301. The exhaust duct 313 has a slit 313a formed along the inner peripheral surface thereof. In addition, an exhaust port 313b is formed in the outer wall of the exhaust duct 313. On the top surface of the exhaust duct 313, a ceiling wall 314 is provided to close the upper opening of the processing container 301. The space between the ceiling wall 314 and the exhaust duct 313 is hermetically sealed with a seal ring 315.

The susceptor 302 is for horizontally supporting a substrate W within the processing container 301. The susceptor 302 has a disk shape with a size corresponding to the substrate W, and is supported by a support member 323. The susceptor 302 is made of a ceramic material or a metal material, and has a heater 321 embedded therein for heating the substrate W. The heater 321 is adapted to generate heat by being fed with power from a heater power source (not illustrated). By controlling the output of the heater 321 by a temperature signal of a thermocouple (not illustrated) provided in the vicinity of a substrate placement surface in the top surface of the susceptor 302, the substrate W is controlled to have a predetermined temperature.

The susceptor 302 is provided with a cover member 322 made of ceramic such as alumina to cover the outer peripheral region of the substrate placement surface and the side surface of the susceptor 302.

The support member 323, which supports the susceptor 302, extends to the lower side of the processing container 301 through a hole formed in the bottom wall of the processing container 301 from the center of the bottom surface of the susceptor 302, and the lower end of the support member is connected to a lifting mechanism 324. The susceptor 302 is configured to be raised and lowered by the lifting mechanism 324 via the support member 323 between the processing position, which is illustrated by the solid line in FIG. 21, and a transfer position, which is illustrated by a one-dot chain line below the processing position and at which a wafer W can be transferred. In addition, the support member 323 is provided with a flange member 325 at a position below the processing container 301, and a bellows 326, which partitions the atmosphere in the processing container 301 from the outside air, is provided between the bottom surface of the processing container 301 and the flange member 325 so as to expand and contract in response to the lifting movement of the susceptor 302.

Three support pins 327 (of which only two are illustrated) are provided in the vicinity of the bottom surface of the processing container 301 to protrude upward from a lifting plate 327a. The support pins 327 are configured to be raised and lowered via the lifting plate 327a by the lifting mechanism 328 provided below the processing container 301, and are inserted into through holes 302a provided in the susceptor 302 located at the transfer position to be capable of protruding or retreating with respect to the top surface of the susceptor 302. By raising and lowering the support pins 327 in this manner, the substrate W is transferred between the substrate transfer mechanism (not illustrated) and the susceptor 302.

The shower head 303 is a metal member for supplying a processing gas into the processing container 301 in the form of a shower, is provided to face the susceptor 302, and has approximately the same diameter as the susceptor 302. The shower head 303 has a main body 331 fixed to the ceiling wall 314 of the processing container 301 and a shower plate 332 connected to the lower side of the main body 331. A gas diffusion space 333 is formed between the main body 331 and the shower plate 332, and in this gas diffusion space 333, a gas inlet hole 336 is provided to penetrate the centers of the main body 331 and the ceiling wall 314 of the processing container 301. An annular protrusion 334 protruding downward is formed at the peripheral edge of the shower plate 332, and gas ejection holes 335 are formed in the flat surface inside the annular protrusion 334 of the shower plate 332.

In the state in which the susceptor 302 is located at the processing position, a processing space 337 is formed between the shower plate 332 and the susceptor 302, and the annular protrusion 334 and the top surface of the cover member 322 of the susceptor 302 come close to each other to form an annular gap 338.

The exhauster 304 is for exhausting the interior of the processing container 301, and includes an exhaust pipe 341 connected to the exhaust port 313b of the exhaust duct 313 and an exhaust mechanism 342 having a vacuum pump, a pressure control valve, or the like connected to the exhaust pipe 341. During the processing, the gas in the processing container 301 reaches the exhaust duct 313 through the slit 313a and is exhausted from the exhaust duct 313 through the exhaust pipe 341 by the exhaust mechanism 342 of the exhauster 304.

The gas supply mechanism 305 is for supplying a plurality of processing gases for film formation to the shower head 303, and has a supply source and supply pipe for each processing gas. As the processing gases, a film forming raw material gas, a reaction gas, an inert gas, and the like are supplied. The inert gas is used as a purge gas, a carrier gas, and a diluent gas. The supply pipe for each processing gas of the gas supply mechanism 305 joins a pipe 366 and reaches the shower head 303.

Various gases may be used as film forming raw material gases depending on the metal of a film to be formed. For example, in the case of a TiN film and a Ti film, TiCl₄ gas, TiI₄ gas, TiBr₄ gas, TiBr₃ gas, TiI₅ gas, and TiF₅ gas may be used. In the case of a NbN film, NbCl₄ gas, NbF₄ gas, NbI₄ gas, NbBr₅ gas, NbF₅ gas, NbOBr₃ gas, NbOCl₃ gas, NbOBr₃ gas, and NbO₂F gas may be used. In the case of a VN film and a V film, VOBr₃ gas, VOCl₃ gas, VOF₃ gas, V(CO)₆ gas, VCl₄ gas, VF₅ gas, VF₄ gas, VOBr gas, VOCl gas, VOBr₂ gas, VOCl₂ gas, and VOF₂ gas may be used. In the case of a WN film and a W film, W(CO)₆ gas, WBr₂ gas, WCl₂ gas, WI₂ gas, WBr₃ gas, WCl₃ gas, WBr₅ gas, WCl₅ gas, WF₅ gas, WOBr₃ gas, WO₂Cl₃ gas, WBr₆ gas, WCl₆ gas, WO₂Br₂ gas, WO₂Cl₂ gas, WO₂I₂ gas, WF₆ gas, WOBr₄ gas, WOBr₄ gas, WOCl₄ gas, and WOF₄ gas may be used. In the case of a TaN film, TaBr₅ gas, TaCl₅ gas, TaF₅ gas, TaI₅ gas may be used. In the case of a MON film and a Mo film, Mo(CO)₆ gas, MoCl₅ gas, MoF₅ gas, MoOCl₃ gas, MoF₅ gas, MoCl₃ gas, MoF₆ gas, MoOF₄ gas, MoOCl₄ gas, and MoO₂Cl₂ gas may be used. In the case of a Ru film, Ru(CO)₁₂ gas, RuBr₃ gas, RuCl₃ gas, RuF₃ gas, RuI₃ gas, RuF₄ gas, and RuF₅ gas may be used. In the case of a Co film and a Ni film, cobalt amidinate or nickel amidinate may be used. In the case of an Al film, trimethylaluminum (TMA) gas may be used. In the case of a Mn film, MnOF₃ gas or MnO₃Cl gas may be used.

In addition, depending on the type of film-forming raw material gas or reaction gas, the gas may be plasmarized by, for example, applying RF power to the shower head 303.

The controller 307 has a main controller configured with a computer (CPU) that controls each component of the film forming apparatus 300, an input device, an output device, a display device, and a storage device. The storage device stores parameters of various processes performed by the film forming apparatus 300. In addition, the storage device includes a storage medium in which programs for controlling processes to be executed by the film forming apparatus 300, that is, processing recipes, are stored. The main controller calls a predetermined processing recipe stored in the storage medium, and causes the film forming apparatus 300 to execute a predetermined process based on the processing recipe.

In the film forming apparatus 300 configured as described above, first, the gate valve 312 is open, and a wafer W is loaded into the processing container 301 through the loading/unloading port 311 and placed on the susceptor 302 by a transfer apparatus (not illustrated). Thereafter, the transfer apparatus is retracted and the susceptor 302 is raised to the processing position. Then, the gate valve 312 is closed to maintain the interior of the processing container 301 in a predetermined reduced pressure state, and the temperature of the susceptor 302 is controlled to a desired temperature by the heater 321.

In this state, a processing gas is supplied from the gas supply mechanism 305 into the processing container 301 to form a desired film on the substrate W by ALD or CVD.

In film formation by ALD, film formation is performed by alternately supplying a raw material gas and a reaction gas into the processing container 301 with purge by an inert gas in the processing container 301 interposed therebetween. For example, when forming a TiN film, TiCl₄ gas as a raw material gas and NH₃ gas as a reaction gas are alternately supplied with purge interposed therebetween. In addition, film formation by CVD is performed by supplying a raw material gas and a reaction gas to the processing container 301 at the same time. Depending on the film-forming raw material gas, film formation may proceed by thermal decomposition of the film-forming raw material gas without using a reaction gas, for example, when forming a Ru film using Ru(CO)₁₂ gas.

When forming both the first metal-containing unit film 2 and the second metal-containing unit film 3 by ALD or CVD, these films may be successively formed by simply switching the processing gases in the film forming apparatus 300 to form the metal-containing film 1.

After the film formation is completed, the interior of the processing container 301 is purged, the susceptor 302 is lowered, the gate valve 312 is open, and the substrate W is unloaded.

### <Other Applications>

Although embodiments have been described above, it is to be considered that the embodiments disclosed herein are exemplary in all respects and is not restrictive. Various types of omissions, substitutions, and changes may be made to above-described embodiments without departing from the scope and spirit of the appended claims.

For example, in the above embodiments, the materials of the first metal-containing unit film and the second metal-containing unit film are illustrated, but these are merely examples, and other metal-containing films may be used. In addition, although the plasma sputtering apparatus 200 is exemplified as an apparatus for performing film formation by PVD, and the film forming apparatus 300 is exemplified as an apparatus for performing film formation by ALD or CVD, the present disclosure is not limited thereto, and various apparatuses may be used. In addition, in the above embodiments, PVD, ALD, and CVD are exemplified as film forming methods, but thin film formation techniques are not limited thereto.

Furthermore, although fine wiring, pillar- or cylinder-structured electrodes, barrier films, and metal hard masks have been exemplified as applications of metal-containing films, the present disclosure is not limited thereto.

### EXPLANATION OF REFERENCE NUMERALS

1: metal-containing film, 2: first metal-containing unit film, 3: second metal-containing unit film, 101, 121, 131, 141, W: substrate, 105: metal film (fine wiring), 110, 111: fine wiring structure, 114: metal-containing film (barrier film), 120, 130: capacitor, 122: metal-containing film (filler-structured lower electrode), 132: metal-containing film (cylinder-structured lower electrode), 140: structure, 143: metal-containing film (metal hard disk), 200: plasma sputtering apparatus, 300: film forming apparatus

What is claimed is:

1. A metal-containing film comprising a laminate structure that does not contain grain boundaries, wherein the laminate structure is formed by alternately laminating a first metal-containing unit film which has a thickness less than a crystal nucleation critical diameter, and a second metal-containing unit film which differs from the first metal-containing unit film and has a thickness less than the crystal nucleation critical diameter.

2. The metal-containing film of claim 1, wherein the first metal-containing unit film and the second metal-containing unit film are metal nitride films or metal films.

3. The metal-containing film of claim 2, wherein the first metal-containing unit film and the second metal-containing unit film are any one of a combination in which one is a metal nitride film and another one is a metal film, a combination in which both are the metal nitride films, and a combination in which both are the metal films.

4. The metal-containing film of claim 3, wherein the metal nitride film is selected from TiN, NbN, VN, WN, TaN, MON, and W₂N₃, and the metal film is selected from Ru, Co, Ni, Mo, W, Al, Ti, V, Mn, Si, and Mg.

5. The metal-containing film of claim 3 or 4, wherein the combination in which one is a metal nitride film and another one is a metal film is selected from TiN—W, TiN—Mo, TiN—Ru, TaN—W, TaN—Mo, and TaN—Ru.

6. The metal-containing film of claim 3 or 4, wherein the combination in which both are metal nitride films is selected from TiN—TaN, TiN—NbN, TiN—MoN, TiN—W₂N₃, TaN—NbN, and TaN—W₂N₃.

7. The metal-containing film of claim 3 or 4, wherein the combination in which both are metal films is selected from Si—Al, W—Al, Mg—Al, W—Ti, V—Ti, and Mg—Ti.

8. The metal-containing film of any one of claims 1 to 4, wherein an element that increases a degree of supercooling is added to at least one of the first metal-containing unit film and the second metal-containing unit film.

9. The metal-containing film of claim 8, wherein the element that increases the degree of supercooling has an interaction parameter of 0 or more with a parent phase material to which the element is added.

10. The metal-containing film of claim 9, wherein, when, of the first metal-containing unit film and the second metal-containing unit film, a metal-containing unit film to which the element that increases the degree of supercooling is added is an Al film, the element that increases the degree of supercooling is Si,
when, of the first metal-containing unit film and the second metal-containing unit film, the metal-containing unit film to which the element that increases the degree of supercooling is added is a Ru film, the element that increases the degree of supercooling is selected from Ir, Pd, Ni, Co, and Mn,
when, of the first metal-containing unit film and the second metal-containing unit film, the metal-containing unit film to which the element that increases the degree of supercooling is added is a Co film, the element that increases the degree of supercooling is selected from Ni, Cu, Pd, and Ru,
when, of the first metal-containing unit film and the second metal-containing unit film, the metal-containing unit film to which the element that increases the degree of supercooling is added is a W film, the element that increases the degree of supercooling is selected from Mo, Ta, Nb, Ti, and Mn,
when, of the first metal-containing unit film and the second metal-containing unit film, the metal-containing unit film to which the element that increases the degree of supercooling is added is a Mo film, the element that increases the degree of supercooling is selected from W, Ta, Nb, Ti, and Mn,
when, of the first metal-containing unit film and the second metal-containing unit film, the metal-containing unit film to which the element that increases the degree of supercooling is added is a Ti film, the element that increases the degree of supercooling is selected from Zr, Hf, V, W, Mo, Nb, and Ta, and
when, of the first metal-containing unit film and the second metal-containing unit film, the metal-containing unit film to which the element that increases the degree of supercooling is added is a Mn film, the element that increases the degree of supercooling is selected from Ru, Fe, Mo, and W.

11. The metal-containing film of any one of claims 1 to 4, wherein the metal-containing film is used as a metal pillar-structured electrode or a cylinder-structured electrode.

12. The metal-containing film of any one of claims 1 to 4, wherein the metal-containing film is used as a barrier film.

13. The metal-containing film of any one of claims 1 to 4, wherein the metal-containing film is used as a wiring metal.

14. The metal-containing film of any one of claims 1 to 4, wherein the metal-containing film is used as a metal hard mask.

15. A method for producing a metal-containing film having a laminate structure which does not contain grain boundaries, the method comprising:
forming a first metal-containing unit film having a film thickness less than a crystal nucleation critical diameter on a substrate; and
forming a second metal-containing unit film which differs from the first metal-containing unit film and has a thickness less than a crystal nucleation critical diameter,
wherein the forming the first metal-containing unit film and the forming the second metal-containing unit film are performed alternately.

16. The method of claim 15, wherein the first metal-containing unit film and the second metal-containing unit film are formed by one of PVD, ALD, and CVD.

17. The method of claim 15 or 16, wherein the first metal-containing unit film and the second metal-containing unit film are metal nitride films or metal films.

18. The method of claim 17, wherein the first metal-containing unit film and the second metal-containing unit film are any one of a combination in which one is a metal nitride film and another one is a metal film, a combination in which both are the metal nitride films, and a combination in which both are the metal films.

19. The method of claim 15 or 16, wherein an element that increases a degree of supercooling is added to at least one of the first metal-containing unit film and the second metal-containing unit film.

20. The method of claim 19, wherein the element that increases the degree of supercooling has an interaction parameter of 0 or more with a parent phase material to which the element is added.
